(19) United States
(12) Patent Application Publication
(10) Pub. No.: US 2026/0282824 A1
(43) Pub. Date: Sep. 17, 2026

(54) SYSTEM AND METHOD FOR CONTACTLESS HANDLING OF SEMICONDUCTOR WAFERS

(71) Applicant: PTW Asia Pte Ltd, Singapore (SG)

(72) Inventor: Christoph Winkler, Bleiberg-Nötsch, Kärnten (AT)

(21) Appl. No.: 19/168,634

(22) PCT Filed: Mar. 22, 2024
(86) PCT No.: PCT/SG2024/050168

§ 371 Date: Sep. 24, 2025

(30) Foreign Application Priority Data
Apr. 6, 2023 (SG) 10202300962S

(51) Int. Cl. H10P 72/30; B25J 11/00; B65G 43/08; B65G 47/244; B65G 51/03

(52) U.S. Cl. CPC H10P 72/3604; B25J 11/0095; B65G 43/08; B65G 47/244; B65G 51/03; B65G 2203/0225; B65G 2203/025; B65G 2811/0626; B65G 2812/16

(57) ABSTRACT

The present disclosure generally relates to a system (100) and method (400) for contactless handling of a semiconductor wafer (200). The system (100) comprises: a wafer table (300) for supporting the semiconductor wafer (200) without physical contact between them, the wafer table (300) comprising fluidic outlets for discharging gas; pneumatic lines (140) for communicating gas to the fluidic outlets; and a pneumatic controller (150) for controlling gas communication in the pneumatic lines (140) to thereby selectively discharge gas from the fluidic outlets. A first set of the fluidic outlets discharges gas therefrom such that the discharged gas contactlessly supports the semiconductor wafer (200) relative to the wafer table (300). A second set of the fluidic outlets discharge gas therefrom such that the discharged gas rotates the semiconductor wafer (200) while the semiconductor wafer (200) is being contactlessly supported by the wafer table (300). The pneumatic controller (150) controls gas discharge from the first and second sets of fluidic outlets to thereby control support and rotation of the semiconductor wafer (200).

### CROSS REFERENCE TO RELATED APPLICATIONS

The present disclosure claims the benefit of Singapore Patent Application 10202300962S filed on 6 Apr. 2023, which is incorporated in its entirety by reference herein.

### TECHNICAL FIELD

The present disclosure generally relates to contactless handling of semiconductor wafers. More particularly, the present disclosure describes various embodiments of a system and a method for contactless handling of semiconductor wafers using gas.

### BACKGROUND

Semiconductor wafer processing operations involve the performance of various types of processing steps or sequences upon a semiconductor wafer. A wide variety of semiconductor device processing operations involve a number of handling systems that perform wafer handling operations which involve securely and selectively carrying semiconductor wafers from one location to another. Particularly, a handling system must retrieve a semiconductor wafer from a wafer cassette and transfer the semiconductor wafer to another station, such as another wafer cassette or a wafer table.

For example, a handling system transfers a semiconductor wafer from a wafer cassette to a wafer table. The wafer table establishes secure retention of the semiconductor wafer prior to the semiconductor process, such as inspection, and releases the wafer after the semiconductor process is complete. Vacuum suction, loosely resting on an end effector, or edge gripping is normally used to secure the semiconductor wafer onto the surface of the wafer table. The planarity of the wafer table surface is thus important in order to securely retain the semiconductor wafer on the wafer table surface. For semiconductor wafers that are very thin, it is important for the wafer table to be ultra-planar, otherwise it would be easy for one or more dies on the semiconductor wafer to become positioned out of the depth of focus during inspection.

Other than the planarity of the wafer table surface, it is important to ensure that the wafer table surface does not contain any particulate matter that would affect the retention of the semiconductor wafer on the wafer table surface. The presence of particulate matter, such as dust particles, results in the semiconductor wafer not sitting properly or uniformly on the wafer table surface. These dust particles can thus contaminate the wafer table surface and may subsequently contaminate the semiconductor wafers which are placed on the wafer table surface, causing yield and reliability problems.

Further, the handling systems are configured to align the semiconductor wafers when they are transferred to another location, especially since semiconductor wafers come in various shapes and sizes. Such aligning operations may include rotating the semiconductor wafer during transfer. One known alignment device for rotating semiconductor wafers is a prealigner that affixes the wafer on a chuck by edge grip, vacuum or electrostatic chucking. The wafer can then be aligned by rotating the wafer on the chuck.

One problem with existing handling systems is that the semiconductor wafers must physically contact the wafer table to be secured by the vacuum chuck or by edge gripping. Another problem is that the alignment devices must physically contact the semiconductor wafers in order to rotate and align them. This increases the risk of contamination and damage to the semiconductor wafers, resulting in yield and quality problems. For example, the physical contact can introduce unwanted dust particles to the wafer surface or induce micro cracks within the wafer material.

Therefore, in order to address or alleviate at least one of the aforementioned problems and/or disadvantages, there is a need to provide an improved system and method for handling of semiconductor wafers.

### SUMMARY

According to a first aspect of the present disclosure, there is a system for contactless handling of a semiconductor wafer. The system comprises:
a wafer table configured for supporting the semiconductor wafer without physical contact between them, the wafer table comprising a plurality of fluidic outlets configured for discharging gas;
a plurality of pneumatic lines fluidically connected to the fluidic outlets for communicating gas to the fluidic outlets; and
a pneumatic controller configured for controlling gas communication in the pneumatic lines to thereby selectively discharge gas from the fluidic outlets,
wherein a first set of the fluidic outlets is configured to discharge gas communicating from the pneumatic lines, such that the discharged gas from the first set of fluidic outlets supports the semiconductor wafer relative to the wafer table without physical contact between them;
wherein a second set of the fluidic outlets is configured to discharge gas communicating from the pneumatic lines, such that the discharged gas from the second set of fluidic outlets rotates the semiconductor wafer while the semiconductor wafer is being supported by the wafer table without physical contact between them; and
wherein the pneumatic controller is configured for controlling gas discharge from the first and second sets of fluidic outlets to thereby control support and rotation of the semiconductor wafer.

According to a second aspect of the present disclosure, there is a method for contactless handling of a semiconductor wafer. The method comprises:
positioning a semiconductor wafer and a wafer table relative to each other, the wafer table comprising a plurality of fluidic outlets configured for discharging gas;
controlling, using a pneumatic controller, gas communication in a plurality of pneumatic lines fluidically connected to the fluidic outlets to thereby selectively discharge gas from the fluidic outlets;
discharging, from a first set of the fluidic outlets, gas communicating from the pneumatic lines, such that the discharged gas from the first set of fluidic outlets supports the semiconductor wafer relative to the wafer table without physical contact between them;
discharging, from a second set of the fluidic outlets, gas communicating from the pneumatic lines, such that the discharged gas from the second set of fluidic outlets rotates the semiconductor wafer while the semiconductor wafer is being supported by the wafer table without physical contact between them;
controlling, using the pneumatic controller, gas discharge from the first and second sets of fluidic outlets to thereby control support and rotation of the semiconductor wafer.

A system and method for contactless handling of a semiconductor wafer according to the present disclosure is thus disclosed herein. Various features and advantages of the present disclosure will become more apparent from the following detailed description of the embodiments of the present disclosure, by way of non-limiting examples only, along with the accompanying drawings.

### BRIEF DESCRIPTION OF THE DRAWINGS

FIGS. 1A to 1C are illustrations of a system for contactless handling of a semiconductor wafer, according to embodiments of the present disclosure.

FIGS. 2A and 2B are illustrations of a wafer table of the system.

FIGS. 3A and 3B are illustrations of a semiconductor wafer suspended above the wafer table of FIGS. 2A and 2B.

FIG. 4 is a flowchart illustration of a method for contactless handling of a semiconductor wafer, according to embodiments of the present disclosure.

FIGS. 5A to 5D are illustrations of another wafer table of the system.

FIGS. 6A and 6B are illustrations of a semiconductor wafer gripped below the wafer table of FIGS. 5A to 5D.

### DETAILED DESCRIPTION

For purposes of brevity and clarity, descriptions of embodiments of the present disclosure are directed to a system and method for contactless handling of a semiconductor wafer in accordance with the drawings. While parts of the present disclosure will be described in conjunction with the embodiments provided herein, it will be understood that they are not intended to limit the present disclosure to these embodiments. On the contrary, the present disclosure is intended to cover alternatives, modifications and equivalents to the embodiments described herein, which are included within the scope of the present disclosure as defined by the appended claims. Furthermore, in the following detailed description, specific details are set forth in order to provide a thorough understanding of the present disclosure. However, it will be recognized by an individual having ordinary skill in the art, i.e. a skilled person, that the present disclosure may be practiced without specific details, and/or with multiple details arising from combinations of features of particular embodiments. In a number of instances, well-known systems, methods, procedures, and components have not been described in detail so as to not unnecessarily obscure features of the embodiments of the present disclosure.

In embodiments of the present disclosure, depiction of a given element or consideration or use of a particular element number in a particular figure or a reference thereto in corresponding descriptive material can encompass the same, an equivalent, or an analogous element or element number identified in another figure or descriptive material associated therewith.

References to “an embodiment/example”, “another embodiment/example”, “some embodiments/examples”, “some other embodiments/examples”, and so on, indicate that the embodiment(s)/example(s) so described may include a particular feature, structure, characteristic, property, element, or limitation, but that not every embodiment/example necessarily includes that particular feature, structure, characteristic, property, element or limitation. Furthermore, repeated use of the phrase “in an embodiment/example” or “in another embodiment/example” does not necessarily refer to the same embodiment/example.

The terms “comprising”, “including”, “having”, and the like do not exclude the presence of other features/elements/steps than those listed in an embodiment. Recitation of certain features/elements/steps in mutually different embodiments does not indicate that a combination of these features/elements/steps cannot be used in an embodiment. As used herein, the terms “a” and “an” are defined as one or more than one. The use of “/” in a figure or associated text is understood to mean “and/or” unless otherwise indicated. The term “set” is defined as a non-empty finite organization of elements that mathematically exhibits a cardinality of at least one (e.g. a set as defined herein can correspond to a unit, singlet, or single-element set, or a multiple-element set), in accordance with known mathematical definitions. The terms “first”, “second”, etc. are used merely as labels or identifiers and are not intended to impose numerical requirements on their associated terms.

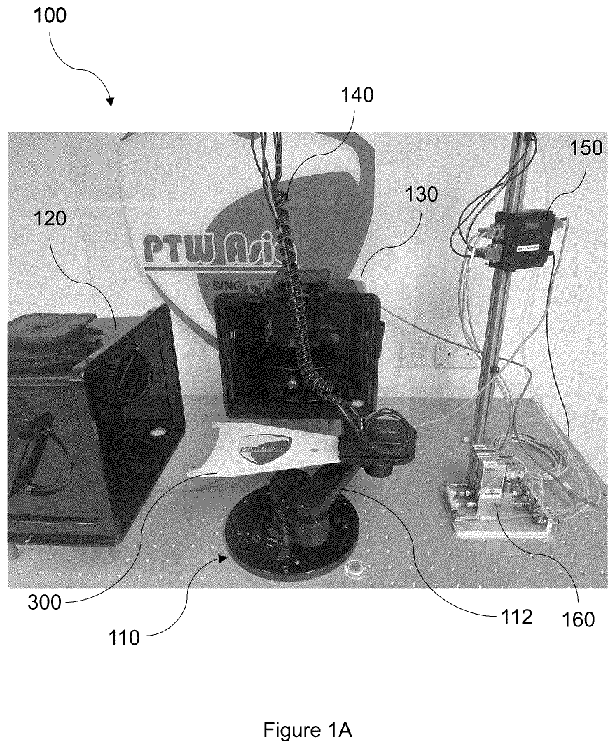

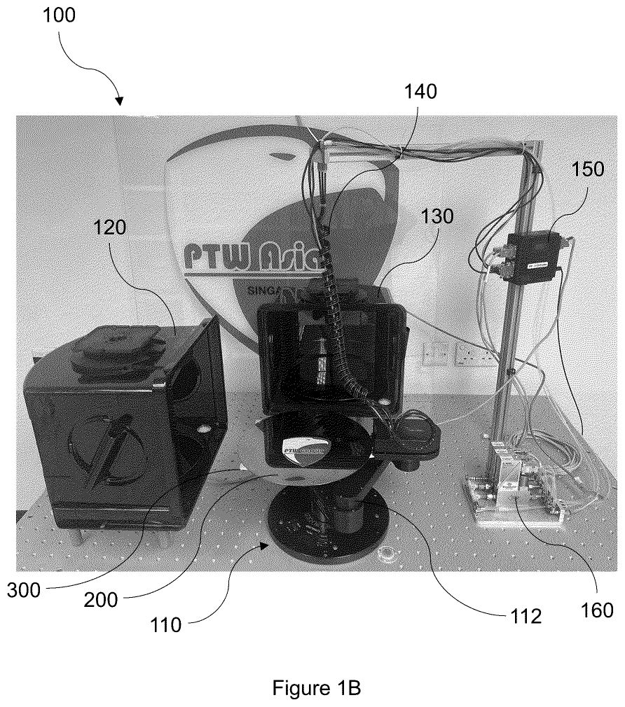

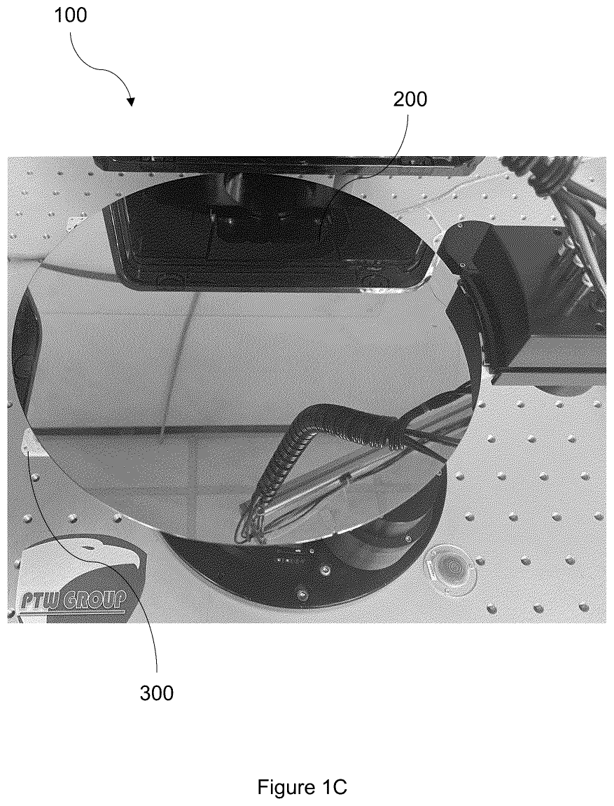

Representative or exemplary embodiments of the present disclosure describe a system 100 for contactless handling of substrates, with reference to FIGS. 1A to 1C. The term “substrate” as used herein can comprise a semiconductor wafer, a partial wafer, a film frame on which a wafer or a portion thereof is mounted. The term “wafer” as used herein can encompass whole wafers, partial wafers, or other types of whole or partial objects or components (e.g. solar cells).

In many embodiments, the system 100 is configured for contactless handling of a semiconductor wafer 200. The system 100 includes a wafer table 300 configured for carrying the semiconductor wafer 200 without physical contact between them, particularly by using gas discharge, as explained further below. Additionally, the term “wafer table” as used herein includes an apparatus for holding a semiconductor wafer 200 or a film frame during a semiconductor process, such as a wafer inspection process or a film frame inspection process, respectively.

In some embodiments, the system 100 includes an arm mechanism 110 coupled to the wafer table 300 and configured for moving the wafer table 300 with the semiconductor wafer 200 from a first station 120 to a second station 130. Particularly, the wafer table 300 is configured for contactlessly carrying the semiconductor wafer 200 during movement from the first station 120 to the second station 130. The stations 120,130 can be located at any suitable locations within a semiconductor process designed for performing various semiconductor operations or steps. For example, the first station 120 may be a wafer cassette storing a stack of semiconductor wafers 200. The second station 130 may be another wafer cassette for receiving a stack of semiconductor wafers 200. Alternatively, the second station 130 may be an inspection station for inspecting the semiconductor wafer 200. Yet alternatively, the second station 130 may be a process chamber or a resting station. It will be appreciated that the first station 120 and second station 130 can be any station within a semiconductor process.

The arm mechanism 110 may include a set of one or more robotic arms 112 configured to move the wafer table 300 up to three mutually orthogonal directions, i.e. the xyz directions. The wafer table 300 is configured to support a semiconductor wafer 200 during movement from the first station 120 to the second station 130. Particularly, as shown in FIG. 1B, the arm mechanism 110 and the wafer table 300 pick the semiconductor wafer 200 from the first station 120, supports the semiconductor wafer on the wafer table 200 without the semiconductor wafer 200 physically contacting the surface of the wafer table 200, and contactlessly moves the semiconductor wafer 200 to the second station 130. The wafer table 300 provides secure retention of the semiconductor wafer 200 after being picked from the first station 120, and releases the semiconductor wafer 200 at the second station 130.

In some embodiments, the system 100 does not include the arm mechanism 110. For example, the wafer table 300 is placed on a stationary chuck and is configured for carrying the semiconductor wafer 200 without physical contact between them.

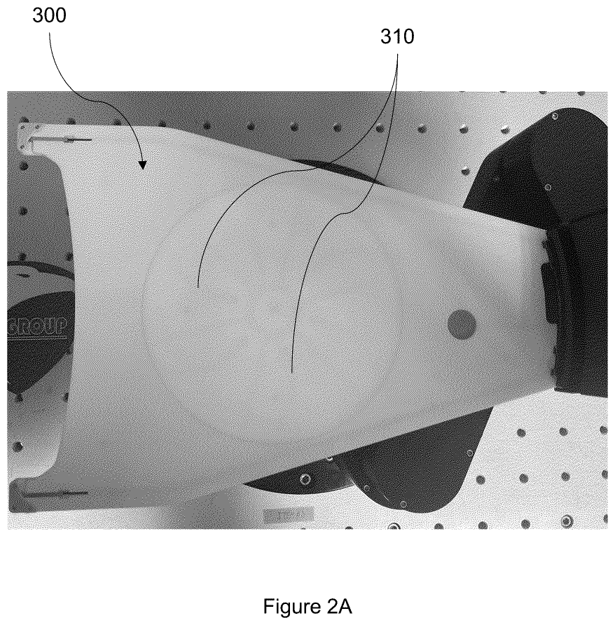

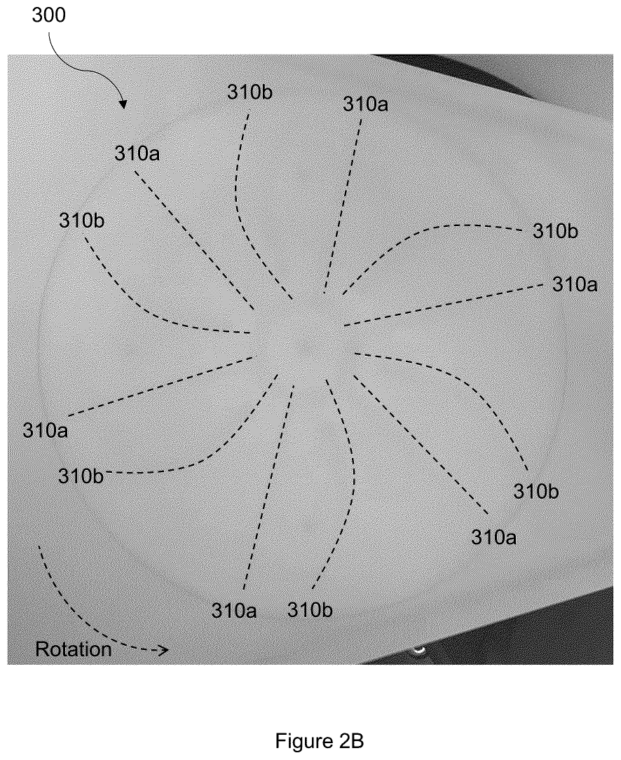

As mentioned above, the wafer table 300 is configured for contactlessly carrying the semiconductor wafer 200 using gas discharge. The wafer table 300 includes a plurality of fluidic outlets, such as fluidic channels 310 as shown in FIGS. 2A and 2B. The system 100 includes a plurality of pneumatic lines 140 fluidically connected to the fluidic outlets for communicating gas to the fluidic outlets. For example, the fluidic outlets are fluidic channels configured to discharge gas, flowing from the pneumatic lines 140, out of the lengthwise profile of the fluidic channels. The gas communicating in the pneumatic lines 140 may include any suitable gas such as air (e.g. clean dry air) or nitrogen. Further, the gas should come from a clean gas source to avoid contaminating the semiconductor wafer 200.

The system 100 further includes a pneumatic controller 150 configured for controlling gas communication in the pneumatic lines 140 to thereby selectively discharge gas from the fluidic outlets. The system 100 may include suitable fluidic components 160, such as pumps and valves, connected to the pneumatic lines 140 and pneumatic controller 150 for supplying the gas and adjusting the gas flow rate in the pneumatic lines 140.

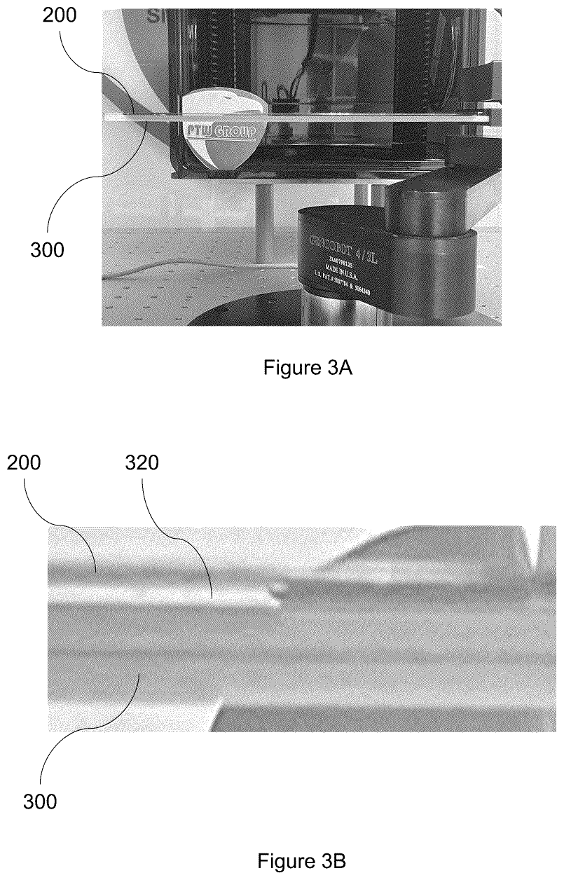

A first set of the fluidic outlets is configured to discharge gas from the pneumatic lines 140, such that the discharged gas from the first set of fluidic outlets supports the semiconductor wafer 200 relative to the wafer table 300 without physical contact between them. For example, the first set of fluidic outlets include the first fluidic channels 310a. FIGS. 3A and 3B show the semiconductor wafer 200 suspended above the surface of the wafer table 300 with a spatial gap 320 between them.

A second set of the fluidic outlets is configured to discharge gas from the pneumatic lines 140, such that the discharged gas from the second set of fluidic outlets rotates the semiconductor wafer 200 while the semiconductor wafer 200 is being supported by the wafer table 300 without physical contact between them. For example, the second set of fluidic outlets include the second fluidic channels 310b. The pneumatic controller 150 is configured for controlling gas discharge from the first and second sets of fluidic outlets, i.e. the first fluidic channels 310a and second fluidic channels 310b, to thereby control support and rotation of the semiconductor wafer 200.

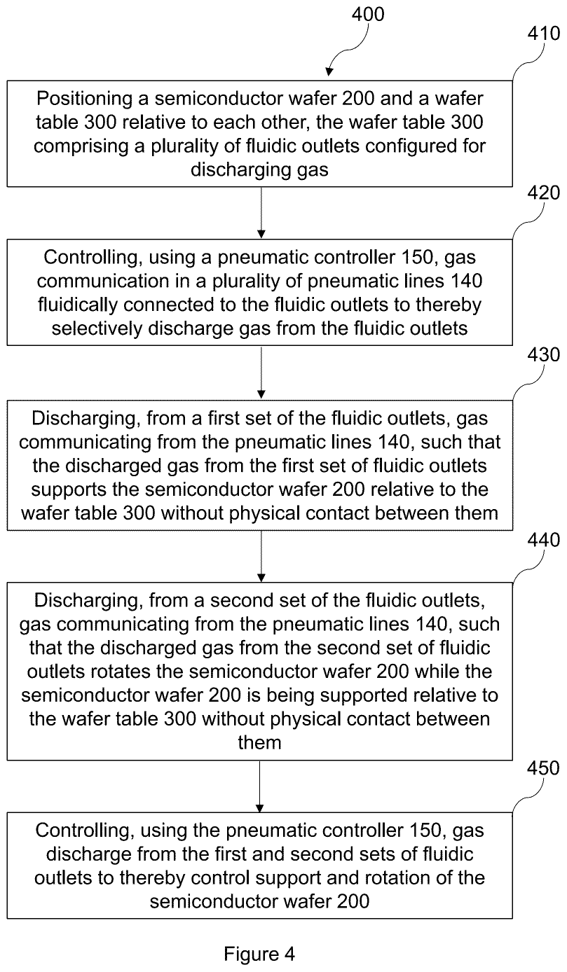

Embodiments of the present disclosure also describe a method 400 for contactless handling of substrates, such as the semiconductor wafer 200, with reference to FIG. 4.

The method 400 includes a step 410 of positioning a semiconductor wafer 200 and a wafer table 300 relative to each other, the wafer table 300 comprising a plurality of fluidic outlets configured for discharging gas. The method 400 includes a step 420 of controlling, using a pneumatic controller 150, gas communication in a plurality of pneumatic lines 140 fluidically connected to the fluidic outlets to thereby selectively discharge gas from the fluidic outlets. The method 400 includes a step 430 of discharging, from a first set of the fluidic outlets, gas communicating from the pneumatic lines 140, such that the discharged gas from the first set of fluidic outlets supports the semiconductor wafer 200 relative to the wafer table 300 without physical contact between them. The method 400 includes a step 440 of discharging, from a second set of the fluidic outlets, gas communicating from the pneumatic lines 140, such that the discharged gas from the second set of fluidic outlets rotates the semiconductor wafer 200 while the semiconductor wafer 200 is being supported by the wafer table 300 without physical contact between them. The method 400 includes a step 450 of controlling, using the pneumatic controller 150, gas discharge from the first and second sets of fluidic outlets to thereby control support and rotation of the semiconductor wafer 200.

In some embodiments as shown in FIG. 2B, the first set of fluidic outlets includes the first fluidic channels 310a and the second set of fluidic outlets includes the second fluidic channels 310b. The first fluidic channels 310a have a profile that enables the discharged gas to suspend the semiconductor wafer 200 above the wafer table 300, such as shown in FIGS. 3A and 3B. The second fluidic channels 310b have a profile that enables the discharged gas to rotate the semiconductor wafer 200 while being suspended above the wafer table 300.

For example, the first fluidic channels 310a include one or more linear fluidic channels. The linear fluidic channels may extend radially outward from around a centre of the wafer table 300. The linear fluidic channels may be equally arranged around the centre of the wafer table 300. Alternatively, the first fluidic channels 310a may include one or more circular channels concentric to the centre of the wafer table 300.

For example, the second fluidic channels 310b may include one or more bent fluidic channels. A bent fluidic channel has a bending angle and may be in the form of a curved or curvilinear channel. For example, the bent fluidic channel may include straight sections that are bent at an angle relative to each other. For example, the bent fluidic channel may include both curved and straight sections.

More specifically, the second fluidic channels 310b are bent such that they are directed towards the desired rotation direction, i.e. clockwise or anticlockwise. For example as shown in FIG. 2B, the second fluidic channels 310b include curvilinear channels that are curved such that they convex towards the anticlockwise rotation direction. The curvature of the second fluidic channels 310b enables the discharged gas to rotate the semiconductor wafer 200 anticlockwise while remaining suspended above the wafer table 300. It will be appreciated that the semiconductor wafer 200 can rotate clockwise if the second fluidic channels 310b are bent such that they are directed towards the clockwise rotation direction.

The wafer table 300 may optionally include additional sets of the fluidic outlets to assist the first and second sets of fluidic outlets in supporting and/or rotating the semiconductor wafer 200. For example, the second fluidic channels 310b may be bent in a way to achieve clockwise rotation of the semiconductor wafer 200, and the wafer table 300 may include a third set of the fluidic outlets, such as third fluidic channels that are bent in another way to achieve anticlockwise rotation of the semiconductor wafer 200. There may also be different sets of the fluidic outlets, such as different sets of bent fluidic channels, that allow for varying speeds of rotation of the semiconductor wafer 200. For example, the second fluidic channels 310b may enable clockwise rotation of the semiconductor wafer 200 at a certain speed, while the third fluidic channels may enable clockwise rotation of the semiconductor wafer 200 at a higher speed. The second and third fluidic channels may complement each other to increase the rotational speed of the semiconductor wafer 200.

As described above, the system 100 includes pneumatic lines 140 fluidically connected to the fluidic outlets. For example, the pneumatic lines 140 may include a first pneumatic line fluidically connected to the first fluidic channels 310a in the wafer table 300. The first fluidic channels 310a are configured for discharging gas communicating from the first pneumatic line. The first fluidic channels 310a have a profile that enables the discharged gas to suspend the semiconductor wafer 200 above the wafer table 300. For example, the first fluidic channels 310a have a linear profile and comprise linear fluidic channels equally distributed on the wafer table 300. The discharged gas from the first fluidic channels 310a pushes the semiconductor wafer 200 upwards, thereby suspending it above the surface of the wafer table 300, such as shown in FIGS. 3A and 3B.

The pneumatic lines 140 may include a second pneumatic line fluidically connected to the second fluidic channels 310b in the wafer table 300. The second fluidic channels 310b are configured for discharging gas communicating from the second pneumatic line. The second fluidic channels 310b have a profile that enables the discharged gas to rotate the semiconductor wafer 200 while being suspended above the wafer table 300. For example, the second fluidic channels 310b have a bent profile and comprise bent fluidic channels. The discharged gas from the second fluidic channels 310b pushes the suspended semiconductor wafer in a clockwise or anticlockwise direction, thereby rotating the semiconductor wafer while it is suspended above the surface of the wafer table 300.

In one example as shown in FIG. 2B, the first fluidic channels 310a include six straight fluidic channels equally arranged on the wafer table 300, and the second fluidic channels 310b include six curved fluidic channels equally arranged on the wafer table 300. The second fluidic channels 310b are curved or bent at an angle to enable rotation of the semiconductor wafer 200 by the discharged gas. More specifically, each second fluidic channel 310b is convex towards the anticlockwise direction, such that the discharged gas rotates the semiconductor wafer 200 anticlockwise. The curved or bent profile of the second fluidic channels 310b enable the discharged gas to attack the semiconductor wafer 200 at an angle and cause it to rotate. The curved or bent profile and the angle can be changed to adjust the rotation speed. For example, the second fluidic channels 310b can be curved with more convex profiles and more acute angles to increase the rotation speed for the same gas flow rate in the second pneumatic line.

It will be appreciated that the flow rate of the gas communicating in the pneumatic lines 140 and discharging from the fluidic outlets for suspending/rotating the semiconductor wafer 200 may vary according to the desired end application of the wafer table 300. For example, the flow rate may range from 10 L/min to 200 L/min, but is not limited to this range.

In some embodiments, the pneumatic lines 140 include a third pneumatic line fluidically connected to the wafer table 300 and configured for braking rotation of the semiconductor wafer 200. For example, the third pneumatic line discharges gas to actuate a brake to stop the rotation.

As described above, the pneumatic controller 150 is configured for controlling the gas discharge from the fluidic outlets to thereby control support and rotation of the semiconductor wafer 200. The controlled rotation enables the semiconductor wafer 200 to be rotated for various semiconductor processing steps. For example, the controlled rotation enables alignment of the semiconductor wafer 200, such as to align it for the second station 130. For example, the pneumatic controller 150 controls the fluidic components 160, such as the pumps and valves, to thereby adjust the gas flow rate in the pneumatic lines 140. For example, the pneumatic controller controls the gas flow rate of the discharged gas from the first fluidic channels 310a to control suspension of the semiconductor wafer 200, such as the size of the spatial gap 320 between the semiconductor wafer 200 and the surface of the wafer table 300. For example, the pneumatic controller 150 controls the gas flow rate of the discharged gas from the second fluidic channels 310b to control rotation of the suspended semiconductor wafer 200. A higher gas flow rate increases the gas discharge velocity and increases the rotation speed.

In some embodiments, the system 100 may include a set of one or more alignment sensors for controlling alignment of the semiconductor wafer 200. Specifically, the alignment sensors are configured for detecting an alignment element of the semiconductor wafer 200. The pneumatic controller 150 may be configured for stopping rotation of the semiconductor wafer 200 in response to the alignment sensors detecting the alignment element. For example, the pneumatic controller 150 stops gas flow in the pneumatic lines, e.g. the second pneumatic line, to stop rotation of the semiconductor wafer 200. The alignment sensors may include optical sensors.

The system 100 may further include a set of one or more preliminary sensors cooperative with the alignment sensors for controlling alignment of the semiconductor wafer 200. Specifically, the preliminary sensors are configured for detecting the alignment element of the semiconductor wafer 200 before the alignment sensors detect the alignment element. The pneumatic controller 150 may be configured for slowing rotation of the semiconductor wafer 200 in response to the preliminary sensors detecting the alignment element. For example, the pneumatic controller 150 adjusts gas flow in the pneumatic lines, e.g. the second pneumatic line, to slow rotation of the semiconductor wafer 200. The preliminary sensors may include optical sensors.

In one example, the alignment element of the semiconductor wafer 200 includes a notch on an edge of the semiconductor wafer 200. As the semiconductor wafer rotates, the preliminary sensors detect the notch and the pneumatic controller 150 slows the gas flow rate in the second pneumatic line, thereby reducing the gas discharge from the second fluidic channels 310b and slowing the rotation of the semiconductor wafer 200. The semiconductor wafer 200 continues rotating at a slower speed until the alignment sensors detect the notch. Upon the alignment sensors detecting the notch, the pneumatic controller 150 stops the gas flow rate in the second pneumatic line, thereby stopping the gas discharge from the second fluidic channels 310b and stopping rotation of the semiconductor wafer 200. The slower rotation of the semiconductor wafer 200 from the detection by the preliminary sensors to the detection by the alignment sensors allows the notch to align with the alignment sensors more accurately, thereby ensuring the semiconductor wafer 200 is accurately aligned for the second station 130.

In one example, the system 100 does not have the preliminary sensors. The pneumatic controller 150 controls the gas flow rate in the second pneumatic line such that the semiconductor wafer 200 rotates at a relatively slower speed. The semiconductor wafer 200 continues rotating at the slower speed until the alignment sensors detect the notch. Upon the alignment sensors detecting the notch, the pneumatic controller 150 stops the gas flow rate in the second pneumatic line, thereby stopping rotation of the semiconductor wafer 200.

In one example, the alignment element of the semiconductor wafer 200 includes a straight edge on the semiconductor wafer. As the semiconductor wafer 200 rotates, the preliminary sensors detect the straight edge and the pneumatic controller 150 slows the gas flow rate in the second pneumatic line, thereby slowing the rotation of the semiconductor wafer 200. For example, the preliminary sensors may include a pair of sensors arranged to detect the straight edge. The semiconductor wafer 200 continues rotating at a slower speed, until the alignment sensors detect the straight edge. Upon the alignment sensors detecting the straight edge, the pneumatic controller 150 stops the gas flow rate in the second pneumatic line, thereby stopping rotation of the semiconductor wafer 200. For example, the alignment sensors may include a pair of sensors arranged to detect the straight edge.

In one example, the system 100 does not have the preliminary sensors. The pneumatic controller 150 controls the gas flow rate in the second pneumatic line such that the semiconductor wafer 200 rotates at a relatively slower speed. The semiconductor wafer 200 continues rotating at the slower speed until the alignment sensors detect the straight edge. Upon the alignment sensors detecting the straight edge, the pneumatic controller 150 stops the gas flow rate in the second pneumatic line, thereby stopping rotation of the semiconductor wafer 200.

An embodiment of the method 400 performed using the system 100 is described as follows. The system 100 includes the arm mechanism 110 for moving the wafer table 300.
1. Move the wafer table 300 using the arm mechanism 110 to the first station 120 to receive a semiconductor wafer 200. The arm mechanism 110 includes robotic arms 112 that are programmed to align to the first station 120 (in the xyz directions) to pick up the semiconductor wafer 200.
2. Position the wafer table 300 below the semiconductor wafer 200 at the first station 120. For example, the first station 120 is a wafer cassette, and the wafer table 300 is positioned below a wafer unit or slot in the wafer cassette 120 using the arm mechanism 110, such as by programming of the robotic arms 112. Particularly, the wafer table 300 does not come into physical contact with the semiconductor wafer 200 at any time. For example, the wafer table 300 may have some guiding elements or pins to help to position the semiconductor wafer 200, but the guiding elements or pins do not physically touch the semiconductor wafer 200.
3. Discharge gas from the first pneumatic line to the first fluidic channels 310 a in the wafer table 300.
4. Suspend the semiconductor wafer 200 above the wafer table 300 using the discharged gas from the first fluidic channels 310a.
5. Carry the semiconductor wafer 200 using the wafer table 300 without physical contact between them.
6. Move the wafer table 300 carrying the semiconductor wafer 200 towards the second station 130 using the arm mechanism 110. For example, the robotic arms 112 are programmed to align to the second station (in the xyz directions) to deliver the semiconductor wafer 200.
7. Discharge gas from the second pneumatic line to the second fluidic channels 310b in the wafer table 300.
8. Rotate the semiconductor wafer 200 while being suspended above the surface of the wafer table 300 using the discharged gas from the second fluidic channels 310b.
9. Control gas flow in the pneumatic lines 140 to control rotation of the semiconductor wafer 200.
10. Align the semiconductor wafer 200 for the second station 130 by said controlled rotation of the semiconductor wafer 200.
11. Optionally slow gas flow in the second pneumatic line to slow rotation of the semiconductor wafer 200 upon alignment of the preliminary sensors.
12. Stop gas flow in the second pneumatic line to stop rotation of the semiconductor wafer 200 upon alignment of the alignment sensors.
13. Position the wafer table 300 at the second station 130. For example, the second station 130 is another wafer cassette, and the wafer table 300 is positioned below a wafer receiving unit or slot in the wafer cassette using the arm mechanism 110, such as by programming of the robotic arms 112.
14. Stop gas flow in the first pneumatic line to stop suspension of the semiconductor wafer 200, thereby dropping the semiconductor wafer 200 to the wafer receiving unit. Notably, the surface of the wafer table 300 is slightly below the wafer receiving unit so that when the semiconductor wafer 200 drops, it does not physically contact the wafer table 300.

Another embodiment of the method 400 performed using the system 100 is described as follows. The system 100 does not include the arm mechanism 110, and the wafer table 300 is placed on a stationary chuck.
1. Position the wafer table 300 below the semiconductor wafer 200. The wafer table 300 may have some guiding elements or pins to help to position the semiconductor wafer 200, but the guiding elements or pins do not physically touch the semiconductor wafer 200.
2. Discharge gas from the first pneumatic line to the first fluidic channels 310a in the wafer table 300.
3. Suspend the semiconductor wafer 200 above the wafer table 300 using the discharged gas from the first fluidic channels 310a.
4. Carry the semiconductor wafer 200 using the wafer table 300 without physical contact between them.
5. Discharge gas from the second pneumatic line to the second fluidic channels 310b in the wafer table 300.
6. Rotate the semiconductor wafer 200 while being suspended above the surface of the wafer table 300 using the discharged gas from the second fluidic channels 310b. The stationary chuck may include a rotational speed sensor or RPM sensor for measuring a rotation speed of the semiconductor wafer 200.
7. Control gas flow in the pneumatic lines 140 to control rotation of the semiconductor wafer 200.
8. Align the semiconductor wafer 200 for the second station 130 by said controlled rotation of the semiconductor wafer 200.
9. Optionally slow gas flow in the second pneumatic line to slow rotation of the semiconductor wafer 200 upon alignment of the preliminary sensors.
10. Stop gas flow in the second pneumatic line to stop rotation of the semiconductor wafer 200 upon alignment of the alignment sensors.

In some embodiments, the wafer table 300 of the system 100 may be replaced by a different wafer table 500 that is similarly configured for discharging gas to support and rotate the semiconductor wafer 200.

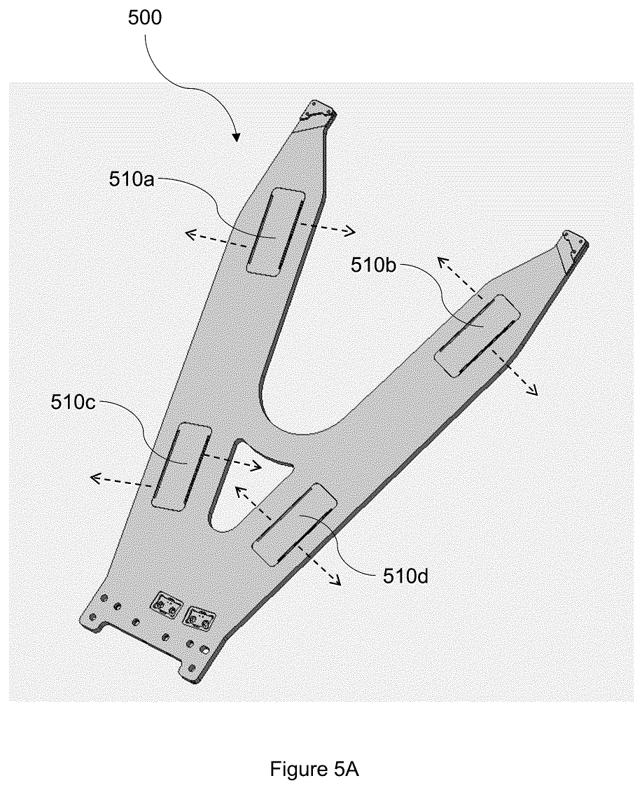

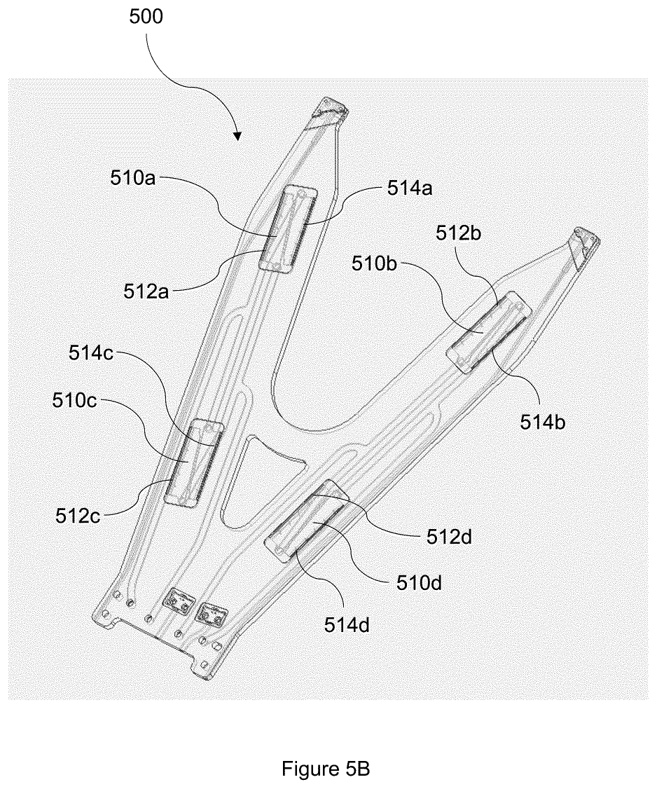

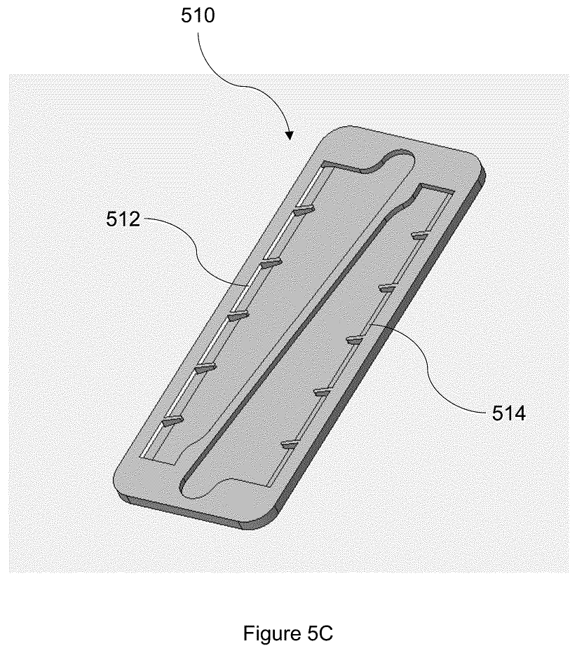

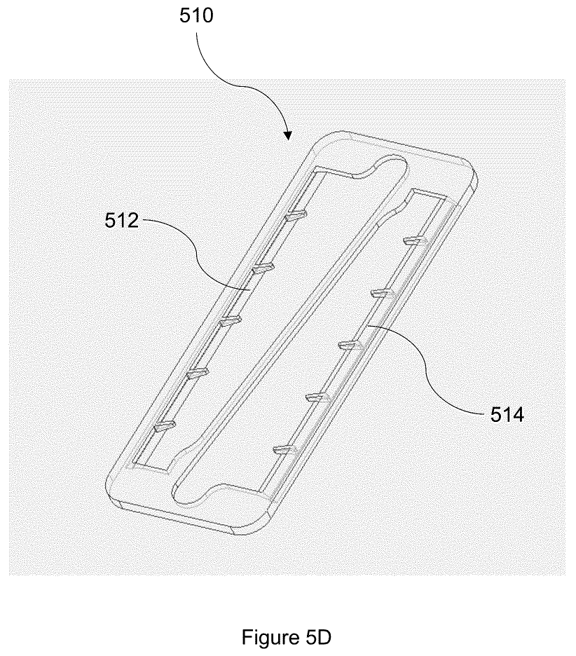

As shown in FIGS. 5A to 5D, the wafer table 500 includes an array of outlet assemblies 510, each outlet assembly 510 having a pair of fluidic channels 512,514 for discharging gas in opposing directions (indicated by the arrows in FIG. 5A) for supporting the semiconductor wafer 200. Specifically, each outlet assembly 510 includes a first fluidic channel 512 arranged to discharge gas in a first direction, and a second fluidic channel 514 arranged to discharge gas in a second direction that is opposite to the first direction.

As described above, the first set of fluidic outlets is configured to discharge gas such that the discharged gas supports the semiconductor wafer 200 relative to the wafer table 500 without physical contact between them, and the second set of fluidic outlets is configured to discharge gas such that the discharged gas rotates the semiconductor wafer 200 while the semiconductor wafer 200 is being supported.

For example, the first set of fluidic outlets includes the pairs of fluidic channels 512,514 of the outlet assemblies 510, such that the discharged gas from the pairs of fluidic channels 512,514 supports the semiconductor wafer 200 relative to the wafer table 500. For example, the second set of fluidic outlets includes a fluidic channel 512,514 of each outlet assembly 510 that discharges gas in a respective direction, such that the discharged gas in the respective directions from the respective fluidic channels 512,514 rotates the semiconductor wafer 200 while being supported by the wafer table 500. The pneumatic controller 150 is configured for controlling gas discharge from the first and second sets of fluidic outlets, i.e. the fluidic channels 512,514, to thereby control support and rotation of the semiconductor wafer 200.

In one embodiment, the discharged gas from the first set of fluidic outlets, i.e. the pairs of fluidic channels 512,514, suspends the semiconductor wafer 200 above the wafer table 500. A spatial gap 520 is formed between the suspended semiconductor wafer 200 and the surface of the wafer table 500. Further, the discharged gas from the second set of fluidic outlets, i.e. the respective fluidic channels 512,514, rotates the semiconductor wafer 200 while being suspended above the wafer table 500. Accordingly, the wafer table 500 discharges gas to suspend and rotate the semiconductor wafer 200, similar to the operation of the wafer table 300 described above.

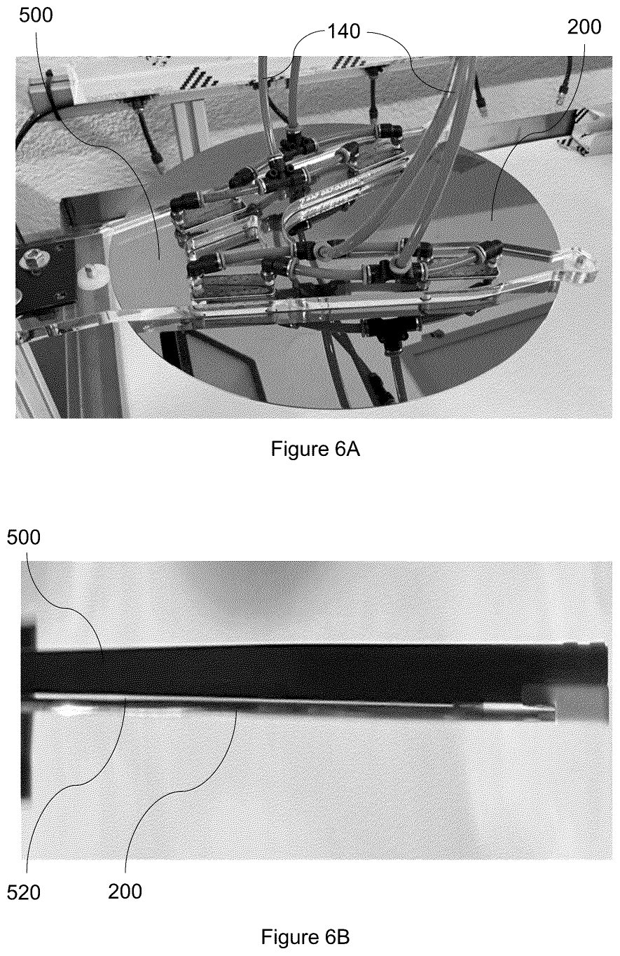

In one embodiment as shown in FIGS. 6A and 6B, the discharged gas from the first set of fluidic outlets, i.e. the pairs of fluidic channels 512,514, grips the semiconductor wafer 200 below the wafer table 500. A spatial gap 520 is formed between the gripped semiconductor wafer 200 and the surface of the wafer table 500. Further, the discharged gas from the second set of fluidic outlets, i.e. the respective fluidic channels 512,514, rotates the semiconductor wafer 200 while being gripped below the wafer table 500.

The contactless gripping of the semiconductor wafer 200 below the wafer table 500 is based on the Bernoulli's principle in fluid dynamics. The Bernoulli's principle states that if a gas flows at high speed over the surface of an object, the local pressure at the object surface will drop. If there is a higher pressure exists on the other surface of the object, there would be a resultant net force towards the object surface with the high speed gas flow. If this force is greater than the object's weight, the object would be drawn towards the lower pressure side. The wafer table 500 discharges gas across the top side of the semiconductor wafer 200 to create the low local pressure side. The bottom side of the semiconductor wafer 200 is at ambient pressure, e.g. atmospheric pressure, that is higher than the low local pressure side. This creates a net force from the bottom side to the top side of the semiconductor wafer 200. This net force exceeds the weight of the semiconductor wafer 200, thus resulting in the semiconductor wafer 200 being drawn towards the wafer table 500. The wafer table 500 thus makes use of gas flow to grip the semiconductor wafer 200 below the wafer table 500 without physical contact between them, while maintaining the spatial gap 520 between them.

For example, with reference to FIG. 5B, gas is discharged from the first pair of fluidic channels 512a,514a, the second pair of fluidic channels 512b,514b, the third pair of fluidic channels 512c,514c, and the fourth pair of fluidic channels 512d,514d to suspend the semiconductor wafer 200 above the wafer table 500 or grip the semiconductor wafer 200 below the wafer table 500.

For example, gas is discharged from the first fluidic channels 512a,512b and second fluidic channels 514c,514d to rotate the suspended/gripped semiconductor wafer 200 anticlockwise. For example for the first outlet assembly 510a, the gas flow rate from the first fluidic channel 512a may be higher than the second fluidic channel 514a to allow for anticlockwise rotation of the suspended/gripped semiconductor wafer 200. Alternatively, the gas flow from the second fluidic channel 514a may be turned off.

For example, gas is discharged from the first fluidic channels 512c,512d and second fluidic channels 514a,514b to rotate the suspended/gripped semiconductor wafer 200 clockwise. For example for the first outlet assembly 510a, the gas flow rate from the second fluidic channel 512b may be higher than the first fluidic channel 512a to allow for clockwise rotation of the suspended/gripped semiconductor wafer 200. Alternatively, the gas flow from the first fluidic channel 512a may be turned off.

It will be appreciated that the flow rate of the gas communicating in the pneumatic lines 140 and discharging from the fluidic outlets for suspending/gripping/rotating the semiconductor wafer 200 may vary according to the desired end application of the wafer table 500. For example, the flow rate may range from 10 L/min to 200 L/min, but is not limited to this range.

It will be appreciated that various aspects described above in relation to the wafer table 300 may apply equally to the wafer table 500, and are not further elaborated for purpose of brevity.

As described above for the wafer table 300, the system 100 includes the pneumatic lines 140 that are fluidically connected to the fluidic outlets of the wafer table 500. For example, the pneumatic lines 140 may include a respective pneumatic line fluidically connected to each of the fluidic channels 512,514 in the wafer table 500, such as shown in FIG. 6A. Similarly, the pneumatic controller 150 controls the gas discharge from the fluidic channels 512,514 to thereby control support and rotation of the semiconductor wafer 200.

The system 100 and method 400 described herein advantageously enable contactless handling of semiconductor wafers 200, i.e. without any physical contact between the semiconductor wafers 200 and the wafer table 300,500. Further, the system 100 is able to rotate and align the semiconductor wafers 200 without making any physical contact with the semiconductor wafers 200. This prevents unwanted dust particles from getting onto the semiconductor wafers 200 which would contaminate them and affect their quality. The absence of any physical contact prevents accidental breakage of the semiconductor wafers 200. There is lower risk of contamination and damage to the semiconductor wafers 200, resulting in improved quality and yield. The processing time of semiconductor wafers 200 in semiconductor manufacturing may also be shortened, thereby increasing the yield output and increased chip yield of each semiconductor wafer 200.

In the foregoing detailed description, embodiments of the present disclosure in relation to a system and method for contactless handling of a semiconductor wafer are described with reference to the provided figures. The description of the various embodiments herein is not intended to call out or be limited only to specific or particular representations of the present disclosure, but merely to illustrate non-limiting examples of the present disclosure. The present disclosure serves to address at least one of the mentioned problems and issues associated with the prior art. Although only some embodiments of the present disclosure are disclosed herein, it will be apparent to a person having ordinary skill in the art in view of this disclosure that a variety of changes and/or modifications can be made to the disclosed embodiments without departing from the scope of the present disclosure. Therefore, the scope of the disclosure as well as the scope of the following claims is not limited to embodiments described herein.

1. A system for contactless handling of a semiconductor wafer, the system comprising:
a wafer table configured for supporting the semiconductor wafer without physical contact between them, the wafer table comprising a plurality of fluidic outlets configured for discharging gas;
a plurality of pneumatic lines fluidically connected to the fluidic outlets for communicating gas to the fluidic outlets; and
a pneumatic controller configured for controlling gas communication in the pneumatic lines to thereby selectively discharge gas from the fluidic outlets,
wherein a first set of the fluidic outlets is configured to discharge gas communicating from the pneumatic lines, such that the discharged gas from the first set of fluidic outlets supports the semiconductor wafer relative to the wafer table without physical contact between them;
wherein a second set of the fluidic outlets is configured to discharge gas communicating from the pneumatic lines, such that the discharged gas from the second set of fluidic outlets rotates the semiconductor wafer while the semiconductor wafer is being supported by the wafer table without physical contact between them; and
wherein the pneumatic controller is configured for controlling gas discharge from the first and second sets of fluidic outlets to thereby control support and rotation of the semiconductor wafer.

2. The system according to claim 1,
wherein the first set of fluidic outlets comprises first fluidic channels having a profile that enables the discharged gas to suspend the semiconductor wafer above the wafer table; and
wherein the second set of fluidic outlets comprises second fluidic channels having a profile that enables the discharged gas to rotate the semiconductor wafer while being suspended above the wafer table.

3. The system according to claim 2, wherein the first fluidic channels comprise one or more linear fluidic channels and/or one or more bent fluidic channels.

4-5. (canceled)

6. The system according to claim 1,
wherein the wafer table comprises an array of outlet assemblies, each outlet assembly comprising a pair of fluidic channels for discharging gas in opposing directions for supporting the semiconductor wafer;
wherein the first set of fluidic outlets comprises the pairs of fluidic channels of the outlet assemblies, such that the discharged gas from the pairs of fluidic channels supports the semiconductor wafer relative to the wafer table; and
wherein the second set of fluidic outlets comprises a fluidic channel of each outlet assembly that discharges gas in a respective direction, such that the discharged gas in the respective directions from the respective fluidic channels rotates the semiconductor wafer while being supported by the wafer table.

7. The system according to claim 6,
wherein the discharged gas from the first set of fluidic outlets suspends the semiconductor wafer above the wafer table; and
wherein the discharged gas from the second set of fluidic outlets rotates the semiconductor wafer while being suspended above the wafer table.

8. The system according to claim 6,
wherein the discharged gas from the first set of fluidic outlets grips the semiconductor wafer below the wafer table; and
wherein the discharged gas from the second set of fluidic outlets rotates the semiconductor wafer while being gripped below the wafer table.

9. The system according to claim 1, wherein the pneumatic lines comprise a pneumatic line configured for braking rotation of the semiconductor wafer.

10. The system according to claim 1, wherein the wafer table is arranged on a stationary chuck, and wherein the stationary chuck comprises a rotational speed sensor for measuring a rotation speed of the semiconductor wafer.

11. (canceled)

12. The system according to claim 1, further comprising an arm mechanism coupled to the wafer table and configured for moving the wafer table with the semiconductor wafer from a first station to a second station, wherein said controlled rotation of the semiconductor wafer enables alignment of the semiconductor wafer for the second station.

13-14. (canceled)

15. The system according to claim 12, further comprising a set of alignment sensors for controlling alignment of the semiconductor wafer, wherein the alignment sensors are configured for detecting an alignment element of the semiconductor wafer, and wherein the pneumatic controller is configured for stopping rotation of the semiconductor wafer in response to the alignment sensors detecting the alignment element.

16. (canceled)

17. The system according to claim 15, further comprising a set of preliminary sensors cooperative with the alignment sensors for controlling alignment of the semiconductor wafer, wherein the preliminary sensors are configured for detecting the alignment element of the semiconductor wafer before the alignment sensors, wherein the pneumatic controller is configured for slowing rotation of the semiconductor wafer in response to the preliminary sensors detecting the alignment element.

18. The system according to claim 15, wherein the alignment element comprises a notch on an edge of the semiconductor wafer.

19. (canceled)

20. A method for contactless handling of a semiconductor wafer, the method comprising:
positioning a semiconductor wafer and a wafer table relative to each other, the wafer table comprising a plurality of fluidic outlets configured for discharging gas;
controlling, using a pneumatic controller, gas communication in a plurality of pneumatic lines fluidically connected to the fluidic outlets to thereby selectively discharge gas from the fluidic outlets;
discharging, from a first set of the fluidic outlets, gas communicating from the pneumatic lines, such that the discharged gas from the first set of fluidic outlets supports the semiconductor wafer relative to the wafer table without physical contact between them;
discharging, from a second set of the fluidic outlets, gas communicating from the pneumatic lines, such that the discharged gas from the second set of fluidic outlets rotates the semiconductor wafer while the semiconductor wafer is being supported by the wafer table without physical contact between them;
controlling, using the pneumatic controller, gas discharge from the first and second sets of fluidic outlets to thereby control support and rotation of the semiconductor wafer.

21. The method according to claim 20, further comprising:
suspending the semiconductor above the wafer table using the discharged gas from the first set of fluidic outlets, the first set of fluidic outlets comprising first fluidic channels; and
rotating the semiconductor wafer while being suspended above the wafer table using the discharged gas from the second set of fluidic outlets, the second set of fluidic outlets comprising second fluidic channels.

22. The method according to claim 20, further comprising:
suspending the semiconductor above the wafer table using the discharged gas from the first set of fluidic outlets, the first set of fluidic outlets comprising pairs of fluidic channels of an array of outlet assemblies of the wafer table; and
rotating the semiconductor wafer while being suspended above the wafer table using the discharged gas in respective directions from the second set of fluidic outlets, the second set of fluidic outlets comprising a fluidic channel of each outlet assembly that discharges gas in a respective direction.

23. The method according to claim 20, further comprising:
gripping the semiconductor below the wafer table using the discharged gas from the first set of fluidic outlets, the first set of fluidic outlets comprising pairs of fluidic channels of an array of outlet assemblies of the wafer table; and
rotating the semiconductor wafer while being gripped below the wafer table using the discharged gas in respective directions from the second set of fluidic outlets, the second set of fluidic outlets comprising a fluidic channel of each outlet assembly that discharges gas in a respective direction.

24-25. (canceled)

26. The method according to claim 20, further comprising:
moving an arm mechanism to a first station to position the wafer table relative to the semiconductor wafer and receive the semiconductor wafer, wherein the arm mechanism is coupled to the wafer table; and
moving the wafer table from the first station to a second station while the semiconductor wafer is being supported by the wafer table without physical contact between them; and
aligning the semiconductor wafer for the second station by said controlled rotation of the semiconductor wafer.

27. (canceled)

28. The method according to claim 26, further comprising:
detecting an alignment element of the semiconductor wafer using an alignment sensor; and
stopping rotation of the semiconductor wafer in response to detecting the alignment element.

29. The method according to claim 26, further comprising:
first detecting an alignment element of the semiconductor wafer using a set of alignment sensors;
slowing rotation of the semiconductor wafer in response to first detecting the alignment element;
second detecting the alignment element using a set of preliminary sensors; and
stopping rotation of the semiconductor wafer in response to second detecting the alignment element.

30. (canceled)

31. The method according to claim 20, wherein the gas communicating in the pneumatic lines comprises clean dry air or nitrogen.
